(19) United States
(12) Patent Application Publication
(10) Pub. No.: US 2014/0150860 A1
(43) Pub. Date: Jun. 5, 2014

(54) ELECTRONIC DEVICE FROM DISSIPATIVE QUANTUM DOTS

(71) Applicant: Dirk K. Morr, Chicago, IL (US)

(72) Inventor: Dirk K. Morr, Chicago, IL (US)

(73) Assignee: The Board of Trustees of the University of Illinoi, Urbana, IL (US)

(21) Appl. No.: 14/117,811

(22) PCT Filed: May 16, 2012
(86) PCT No.: PCT/US2012/038130

§ 371 Date: Feb. 18, 2014

Related U.S. Application Data
(60) Provisional application No. 61/486,638, filed on May 16, 2011.

(51) Int. Cl. H01L 31/0352; H01L 21/66; H01L 29/15

(52) U.S. Cl. CPC H01L 31/035236; H01L 29/15; H01L 22/12
USPC 136/255; 257/15; 438/14

(57) ABSTRACT

An example electronic device includes a region formed from an array of dissipative quantum dots. The quantum dots are arranged according to their electronic structure to provide a tailored asymmetry in current flow through the region.

### PRIORITY CLAIM AND REFERENCE TO RELATED APPLICATION

This application claims the benefit of U.S. Provisional Patent Application Ser. No. 61/486,638, filed May 16, 2011, under 35 U.S.C. §119.

### STATEMENT OF GOVERNMENT INTEREST

This invention was made with government support under grant No. DE-FG02-05ER46225 awarded by Department of Energy. The government has certain rights in the invention.

### FIELD

A field of the invention is electronic devices. Example applications of the invention include diodes. More particular examples include diodes for use in logical gates.

### BACKGROUND ART

It is useful in the art of electronics to minimize the size of electronic devices for increasing portability, reducing power consumption, and/or increasing density. One example electronic device is a diode. Diodes generally are two-contact electronic devices that restrict current flow mainly to one direction. As one particular example, diodes are used as building blocks in logical gates, a key component for many electronic applications. Diodes used for logical gates, such as on a chip, conventionally have been formed from semiconductors.

It has been possible thus far to shrink the size of diodes and increase the density of the diodes on a chip (and thus increase the computing ability of the chip). However, such improvements are becoming progressively more difficult.

### SUMMARY

An example electronic device includes a region formed from an array of dissipative quantum dots. The quantum dots are arranged according to their electronic structure to provide a tailored asymmetry in current flow through the region.

### BRIEF DESCRIPTION OF THE DRAWINGS

FIG. 1 shows an example embodiment diode including a region having a one-dimensional array of quantum dots;

FIG. 2 shows an example scanning tunneling microscope (STM) setup for determining an electronic structure of a quantum dot;

FIG. 3 shows an example interaction between fermions and local phonons;

FIG. 4 shows local density of states (LDOS) for a single quantum dot;

FIG. 5 shows an example one-dimensional array of n quantum dots, indicating electronic levels;

FIG. 6 shows a relationship between LDOS and energy for a one-dimensional array of N=20 quantum dots at the site of the center and edge dots;

FIGS. 7-9 show properties of non-disordered arrays, where FIG. 7 shows a relationship between the chemical potential of a quantum dot and its position, FIG. 8 shows a relationship between current and the applied voltage, and FIG. 9 shows a relationship between resistance and number of dots;

FIG. 10 shows a relationship between the current through the array and temperature (for constant applied voltage) for a non-disordered array;

FIG. 11 shows a relationship between current and voltage for a non-disordered system and two disordered systems;

FIGS. 12A-12B show relationships between position of a quantum dot in the array, the positions of its energy level and chemical potential (FIG. 12A), and between current and temperature (FIG. 12B), for weakly disordered arrays of quantum dots;

FIGS. 13A-13B show relationships between the position of a quantum dot in the array, the positions of its energy level and chemical potential (FIG. 13A), and between current and temperature (FIG. 13B), for strongly disordered arrays of quantum dots;

FIG. 14 shows a relationship between the position of a quantum dot, the positions of its energy level and chemical potential, for a strongly disordered array of quantum dots, illustrating how spatial symmetry of chemical potentials is broken when the bias across the array is reversed due to the disordered energy levels, leading to a change in the magnitude of the current through the quantum dot array;

FIGS. 15A-15B show a relation between the position of a quantum dot, the positions of its energy level and chemical potential, for an example one-dimensional array of quantum dots, where the dots are arranged in order of descending position of energy levels (an example custom disordered array), for forward (FIG. 4A) and reversed (FIG. 4B) bias;

FIG. 15C shows a relation between current and applied bias for the one-dimensional array of quantum dots as arranged in the diode of FIGS. 15A-15B, demonstrating the effect of a diode, and demonstrating a tailored forward bias; and

FIG. 16 shows an example charge valve in a solar device, according to another embodiment.

### DETAILED DESCRIPTION

An example electronic device includes a region formed from an array of dissipative quantum dots. The quantum dots are arranged according to their electronic structure to provide a tailored asymmetry in current flow through the region. Quantum dots (“dots”) refer to electronic systems that possess discrete energy levels. “Dissipative” and “incoherent” refer to a quantum dot whose energy levels possess a finite, non-zero energy width due to interactions. Stated another way, the energy level possesses a finite lifetime. A consequence of the dissipative/incoherent nature of the quantum dots in the array is that the electrons moving through the array dephase.

One nonlimiting example electronic device for which a tailored asymmetry can be provided is a diode. The idea of creating a diode from dissipative quantum dots is based on an observation that the invariance of the current under bias reversal is lost when the dots are dissipative and the array of quantum dots is disordered. A disordered array is one in which the quantum dots are not identical because, for example, the energy position or the energy levels of the dots is different from dot to dot.

Quantum dots can have natural width and position of energy levels, and can thus naturally be dissipative or incoherent, depending on their size, number of atoms, number of energy levels, diameter, inclusion of defects, the interaction of electrons with phonons (lattice vibrations) or other collective modes such as charge modes or magnetic modes, etc. However, with example quantum dots, it is also possible to customize the amount of dissipation by controlling one or more of these factors. Thus, dissipation in quantum dots can be provided using any of various methods, including combinations of methods. A variation in the energy levels of the dots can be achieved in an example embodiment by using dots of slightly different size. A dissipative state can also be custom-designed, for example, through the inclusion of defects in a quantum dot, or the placement of a quantum dot on a substrate. The substrate can be configured to selectively provide dissipation to several quantum dots.

According to an example embodiment, by arranging quantum dots in an order that is determined by their electronic structure (referred to herein as custom disordering, as opposed to non-disorder or random disorder), a diode can be provided with a tailored asymmetry in the current flow (i.e., the magnitude of the current) between forward and reverse directions of the applied potential difference across the region. The respective electronic structures of the individual quantum dots can result in different respective energy levels of the arranged quantum dots. By selection and arrangement of the quantum dots, dissipation of particular quantum dots, and the resulting asymmetry in current flow, can be tailored. Further, as a result of the tailored asymmetry, the forward bias of the diode can be tailored. Diodes provided in this way can also be minimized in size, as quantum dots can made very small, and the number of quantum dots that are used can be optimized for providing a particularly sized diode.

Examples will now be discussed with respect to the drawings. The drawings include schematic figures that are not to scale, which will be fully understood by skilled artisans with reference to the accompanying description. Features may be exaggerated for purposes of illustration. From the provided examples, artisans will recognize additional features and broader aspects.

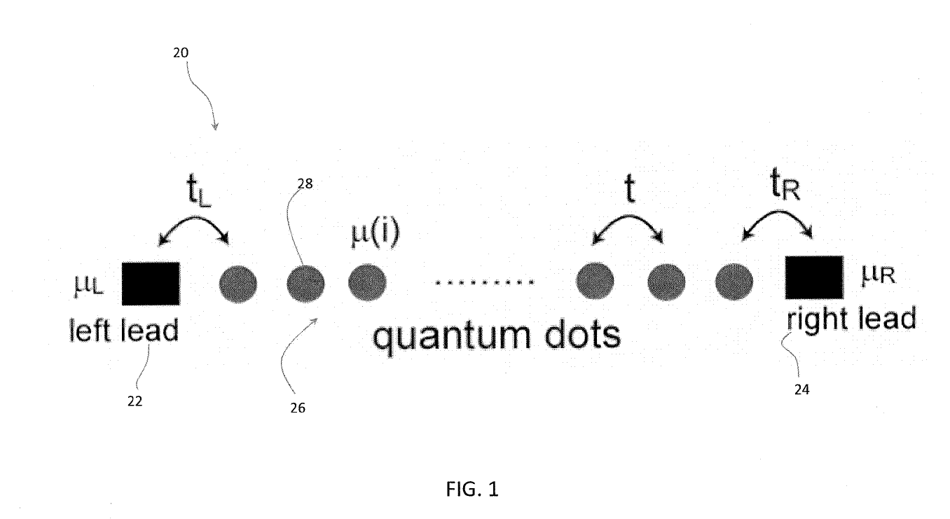

FIG. 1 shows an example diode, generally indicated as 20. The diode 20 includes a first contact 22 and a second contact 24. Nonlimiting examples of the contacts 20, 24 include contacts for known diodes, and such contacts can be made from suitable conductive materials, e.g., conductive metals (as nonlimiting examples, copper or silver).

A region, generally indicated at 26, is disposed between the first contact 22 and the second contact 24. This region includes an arrangement of dissipative quantum dots 28. This arrangement is in a spatial order such that electrons can tunnel from one dot 28 to the next in order to ensure the flow of a current. The arrangement of quantum dots (generally referred to as an array) can be one-dimensional, two-dimensional or three-dimensional in nature. A region generally refers to an arrangement of quantum dots, and does not require a particular geometry.

A nonlimiting example quantum dot 28 arrangement may be one-dimensional, e.g., a chain (as shown in FIG. 1), or multi-dimensional. The region 26 including the quantum dots 28 may be placed on a substrate (not shown), but need not necessarily be placed on a substrate. Alternatively the quantum dots 28 can be ligated with molecules such as dodecanethiol, etc. (not shown) in order to provide free-floating networks. The quantum dots 28 in the region 26 can be, but need not be, housed within materials such as but not limited to insulators. Insulators can also be used in an example embodiment to separate layers or chains of quantum dots to limit effects such as, but not limited to, electrical breakdown.

Nonlimiting materials for the quantum dots 28 include cadmium-selenium (Cd—Se), silicon/silicon-germanium (Si/SiGe) heterostructures, and aluminum gallium arsenic/gallium arsenic (AlGaAs/GaAs) heterostructures, Other example quantum dot materials include metallic quantum dots (e.g., gold), molecules (such as but not limited to biological molecules), atoms (e.g., different elements), etc.

The first and second contacts 22, 24 may be coupled, e.g., electrically coupled, to the region 26, such as by any suitable method, e.g., by bringing the region in direct contact with the contacts, or by any other method that ensures that electrons can tunnel from the contacts into the region. These first and second contacts 22, 24 can then be coupled to other circuit components, as will be appreciated by those of ordinary skill in the art. In an example embodiment, though not necessary in every embodiment, a voltage source is coupled across the first and second contacts to provide an applied potential difference, e.g., a forward or reverse bias, to the diode 20.

The dissipative quantum dots 28 in the region 26 respectively vary in electronic structure between the first contact 22 and the second contact 24. This electronic structure may be due to the quantum dots' 28 size, number of atoms, number of energy levels, diameter, etc. The respective electronic structure of the dissipative quantum dots 28 results in different respective energy levels (i.e., different energy position or width of energy levels, or both) among the quantum dots. Though in an example embodiment each of the dissipative quantum dots 28 has a different electronic structure, it is contemplated that among the quantum dots, more than one dot may have a similar electronic structure, so long as the electronic structures in general vary with respect to one another.

The quantum dots 28 can be arranged (custom disordered, as opposed to complete disorder, i.e., randomness) according to their electronic structure (e.g., according to energy levels) to provide a tailored asymmetry in the current flow between forward and reverse directions of an applied potential difference across the region 26, as well as a tailored forward-bias. This tailored asymmetry provides an asymmetry in the magnitude of the current between a path from the first contact 22 to the second contact 24, and in the reverse direction. The asymmetry can vary in an example embodiment with the magnitude of the applied bias.

In an example embodiment, the tailored asymmetry provides a predetermined (e.g., determined due to a particular determined arrangement) restriction to the current flow when the diode 26 is reverse biased. The tailored asymmetry in the magnitude of the current between the forward and reverse bias may be, as nonlimiting examples, a factor of 5, 10, 20, 100, or higher. As will be understood by those of ordinary skill in the art, the particular tailored asymmetry can vary widely depending on the desired application as well as the materials and environments provided for the diode 26.

The arrangements of the quantum dots 28 with respect to their electronic structure to provide a tailored asymmetry can vary. In an example embodiment, the dissipative quantum dots 28 are arranged in respectively increasing energy position of their energy levels between the first contact 22 and the second contact 24. In another embodiment, the dissipative quantum dots 28 are arranged in respectively decreasing energy position of their energy levels between the first contact 22 and the second contact 24. Arrangements of the quantum dots 28 can also be by a combination of energy level position and energy level width. Generally, the quantum dots 28 can be arranged in the region 27 in any suitable way based on their electronic structure, so as to achieve a certain asymmetry in the current flow. In a nonlimiting example, to maximize asymmetry and provide the largest effect, an embodiment may include quantum dots, each slightly different in size (or significant numbers of the dots being slightly different in size), arranged in an array from largest to smallest or vice versa, providing a tailored disorder.

In another example embodiment the quantum dots 28 are arranged by providing a plurality of quantum dots and introducing respective varying dissipation in the quantum dots. One method of changing the dissipation (i.e., the energy width of their energy levels) in each of the quantum dots 28 is by coupling the quantum dots to a substrate (not shown) that is configured to selectively provide dissipation to each of the quantum dots. Moreover, the electronic levels of the quantum dots can be shifted by backgating the substrate that they are located on. This backgating can occur individually for each quantum dot, thus providing another way to create custom-designed disorder. Thus, the energy position and the energy width of the energy levels in each quantum dot can be custom-designed. This allows one to create custom-designed diodes. As another example, an inhomogeneous substrate can be provided to which the quantum dots are selectively coupled to respectively shift the energy position of the energy levels and the energy width of the energy levels. In other examples, dissipation can be provided by the presence of phonons (lattice vibrations) or other collective modes in the quantum dots. Thus, the arranged quantum dots can be provided with respective electronic structures (and dissipative effects) before or after the dots are physically arranged.

To provide a particular diode effect, that is, to provide a diode 20 with a particular desired current asymmetry (e.g., including tailored forward bias), knowledge of the quantum dots' 28 electronic structure is useful. An example method for forming a diode provides the quantum dots 28 (which can be grown via customary methods), determines their electronic structure, and arranges them in a spatial configuration which is determined by the desired asymmetry in the current to provide the region 26. The quantum dots when provided in the diode are dissipative or can be made dissipative (e.g., due to an electron-phonon interaction, or an interaction of the electronic degrees of freedom on a quantum dot with those of a substrate (not shown) that the dot is placed upon).

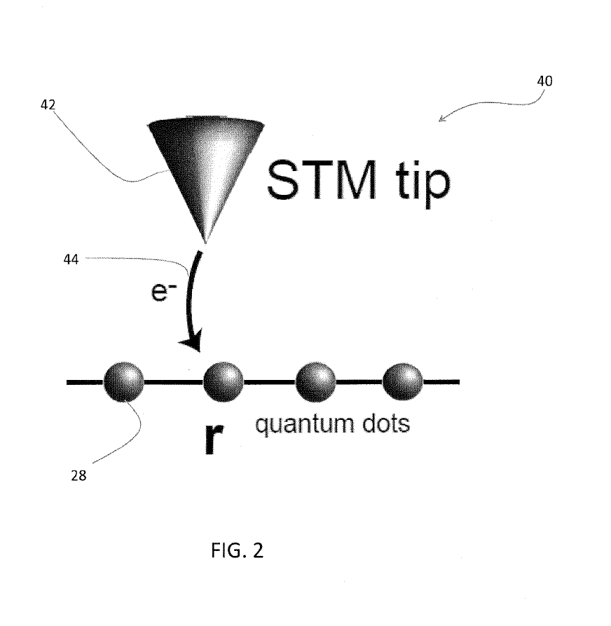

Nonlimiting example methods for determining electronic structure (e.g., the local density of states) of a quantum dot or an arrangement of quantum dots use a scanning tunneling microscope (STM). FIG. 2 shows an example STM setup 40 including a scanning tunneling microscope (STM) tip 42, which measures the local density of states (LDOS) on a quantum dot 28. In FIG. 2, e− indicates electrons 44 tunneling from the tip 42 into the quantum dot 28 (or vice versa), i.e., the current that flows between the tip and the quantum dots, and r indicates a spatial position. The density of states provides direct information on the energy position and the energy width of the energy levels in a quantum dot. Other methods for determining electronic structure are also possible.

Having determined the electronic structures of particular quantum dots 28, and determining (e.g., calculating) the asymmetry for one or more arrangements of quantum dots, one can select an order for arranging the quantum dots. For example, the calculated asymmetry for one or more arrangements may be used to design an arrangement order for a given target asymmetry. For particular example quantum dots (e.g., CdSe, Si/SiGe heterostructures, AlGaAs/GaAs heterostructures, and others), the energy position and/or energy width of a single electronic level can be used to select and arrange the quantum dots. However, energy widths and/or energy positions of multiple electronic levels can also be considered in arranging the quantum dots.

Given the determined arrangement order, atomic manipulation can be used in an example method to arrange the quantum dots in a particular spatial configuration, though other methods of arranging are possible. A nonlimiting example arrangement is a finite, one-dimensional array of quantum dots. An example arrangement is performed such that respective distances between the arranged plurality of quantum dots permit electrons of the arranged quantum dots to tunnel into adjacent ones of the quantum dots. Nonlimiting examples include using a tip of the STM to manipulate the quantum dots. Various arrangements can be used for achieving a particular target asymmetry or range.

The asymmetry in the current through the array of quantum dots is determined by both the disorder (i.e., variation in the energy position of the energy levels) and the dissipation in the array. The asymmetry in the current decreases when the dissipation goes to zero or when the dissipation goes to infinity. As a result, there can be an optimal dissipation (for a given non-zero realization of disorder) for which the asymmetry is maximal (though it is not required that such an optimal dissipation be used). Similarly, for a given non-zero, non-infinity realization of dissipation in the array of quantum dots, there are one or more realizations of disorder for which the asymmetry in the current is maximal (though it is not required that the maximal asymmetry be used). For a desired asymmetry in the current, multiple realizations of custom-designed disorder and/or dissipation might exist.

The quantum dots can be arranged on and coupled to a substrate. This substrate may also be selected, configured, or both for tailored dissipation; that is, for an effect of the substrate on dissipation of the quantum dots. For example, when the substrate is an insulator, the dissipation induced in the quantum dots due to coupling to the substrate (and the resulting hopping of electrons between the quantum dots and the substrate, in which case the substrate would act as a electron reservoir) is expected to be the lowest, while if the substrate is a conductor, the induced dissipation is expected to be the highest. Example design methods can thus take into account the substrate effect. The substrate can be backgated to cause selective energy positions and energy width (dissipation) of the energy levels in the quantum dots. Atomic manipulation (such as, but not limited to, using an STM) may be used to arrange the quantum dots on the substrate. In other methods omitting a coupled substrate, atomic manipulation may be used to arrange the quantum dots in a floating network.

The plurality of quantum dots can be caused to be dissipative, implying a non-zero (finite) width of the respective energy levels of the arranged quantum dots. As a nonlimiting example, the quantum dots can be placed on a suitably selected or configured (or both) substrate to provide dissipative effects, as explained above. In other methods, the electrons residing in the electronic levels of the quantum dots can interact with phonons or other collective modes, which as nonlimiting examples, are spin, magnetic or charge modes. This interaction induces a non-zero energy width of the energy levels in the quantum dots and thus leads to dissipation. To control current in an example method, the diode 20 is provided, including the first contact 22, the second contact 24, and the region 26 including an arrangement (e.g., an array) of quantum dots 28, as provided herein. A voltage source (not shown) is coupled across the first contact 22 and the second contact 24, and a potential difference is applied across the region 26. The tailored asymmetry provided by example diodes 20 can provide a significant difference in current across the region 26 depending on the bias direction.

Those of ordinary skill in the art will appreciate various applications for the diodes 20. Nonlimiting example applications include the use of such a diode (with a large custom-designed current asymmetry) as a rectifier allowing the conversion of alternating currents into direct currents. Another example embodiment uses a diode with a large current asymmetry as an over-voltage protection. Yet another example embodiment uses a diode as a basic building block for logical gates and computer chips. Other example applications include light emitting diodes (LEDs) and other analog and/or digital uses. The tailored forward bias provided by an example diode can be useful in applications such as but not limited to voltage reference, temperature sensing, etc. However, it is to be appreciated that these are example applications only, and the diodes can be used in many other applications, including many applications for conventional diodes.

Principles behind an example embodiment will now be discussed. A small electronic system (a quantum dot) possesses discrete energy levels, whose energy spacing can be much larger than room temperature. Thus, the term “quantum dot” generally refers to an electronic system that possesses discrete energy levels. Atoms, molecules, and crystals can be examples of quantum dots.

As long as the electrons located in electronic states of this quantum dot do not interact with the outside environment (for example, they are not located on a substrate), and as long as the electrons do not interact with themselves, or collective modes, such as phonons, or spin, magnetic and charge modes, an electron located in one of these energy levels can in general not transition to another level. One then says that the electronic level (or more precisely the electron in the level) is infinitely long-lived. As a consequence, the width of the energy level is infinitely small.

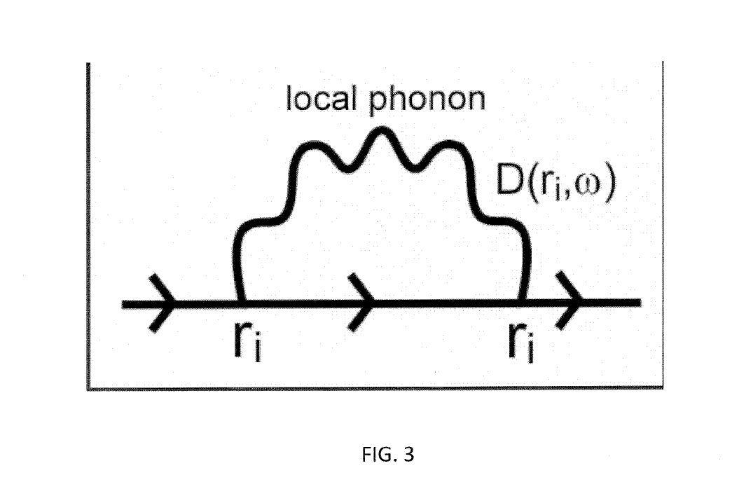

However, when the electrons interact with the outside, or with themselves or with collective modes, for example, by being scattered of a lattice vibration (i.e., a phonon), by tunneling into another electronic level in a substrate, etc., the electronic state of the quantum dot acquires a finite lifetime, and the width of the energy level increases, i.e., the width has a finite, non-zero value. One then says that the energy levels of the dot are dissipative. As a nonlimiting example, FIG. 3 shows an interaction between fermions and overdamped local phonons, in which the properties of the phonons are described by their propagator

$$D ( ω ) = \frac{α}{{( ω + i y )}^{2} - {ω}_{0}^{2}} \qquad ( 1 )$$

where D(ω) refers to the propagator of the phonons, ω refers to the frequency of the phonons, i denotes an imaginary number, γ refers to the inverse lifetime of the phonon modes, ω₀ refers to the energy of the phonons, and α refers to an overall constant describing the strength of the phonons. For dissipative dots,

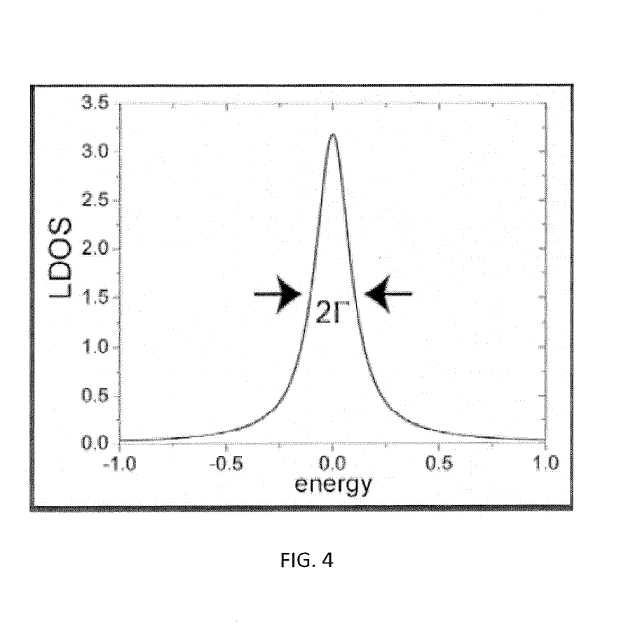

g_{R}⁻¹(r,ω)=ω−ε₀(r)+iΓ(T) (2)

where g_{R}⁻¹ refers to the inverse electronic Greens function of a quantum dot located at spatial position r, r refers to the position of the dot in the array of quantum dots, ε₀(r) refers to energy position of the energy level of the quantum dot located at r, Γ refers to the energy width of the energy level ε₀(r) of the quantum dot located at r, and T refers to temperature. FIG. 4 shows a local density of states (LDOS) for a single quantum dot.

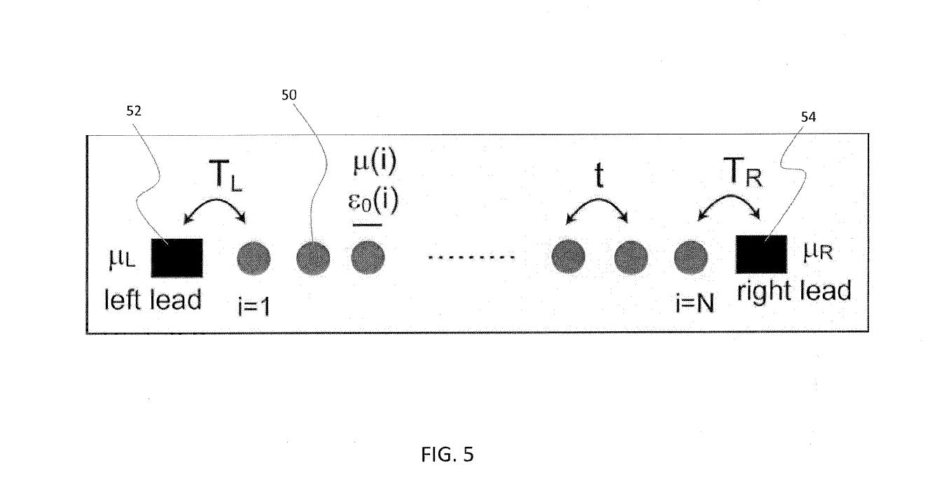

Next, consider a one-dimensional chain made of N identical quantum dots 50 (i.e., a non-disordered array) disposed between a left contact 52 and a right contact 54, as shown in FIG. 5. It is assumed that the quantum dots are dissipative, for example, because they are located on a substrate or interact with phonons. The extent of the dissipation can be controlled by how strongly the dots interact with the substrate, or whether the quantum dots contain phonon modes. By arranging the quantum dots sufficiently close, electrons can tunnel from one dot onto the next one. If one now connects the two external contacts 52, 54 to the ends of this array of quantum dots 50, and applies a voltage difference to these two contacts, an electric current will flow through the one-dimensional array. Since the dots are dissipative, this one-dimensional structure exhibits an electric resistance. This same phenomenon also occurs in, for instance, a piece of copper. However, in this latter case the electronic states are not discrete.

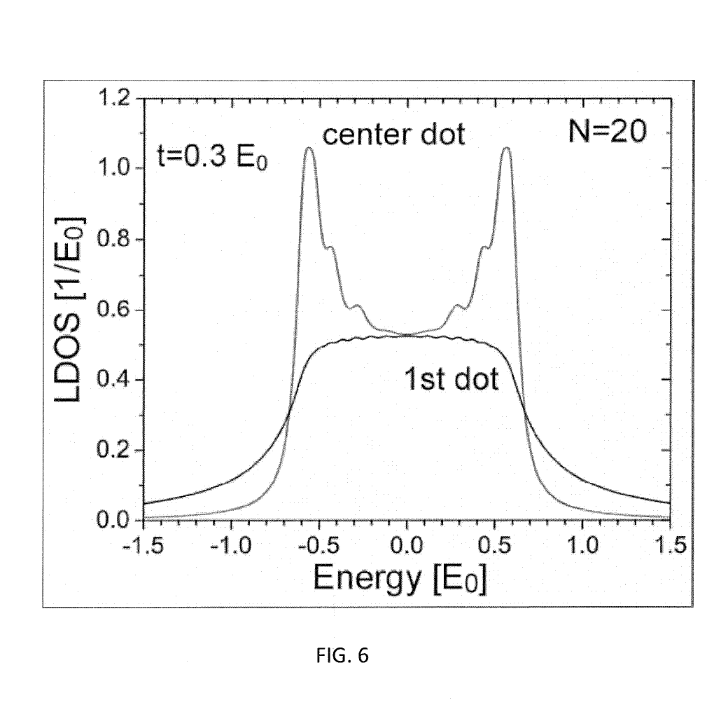

For non-dissipative quantum dots, current conservation yields a constant chemical potential, also referred to as an electro-chemical potential (ECP), μᵢ=const. For dissipative dots, current conservation requires a spatially varying μᵢ. The resistance of this array of quantum dots implies that there is a potential difference between two neighboring dots, which is reflected in a difference in their electro-chemical potential (ECP), μ. In the array of dots 50 shown in FIG. 5, each dot is described by a single electronic level according to equation (2). FIG. 6 shows example LDOS and energy for the first dot and the center dot in an example one-dimensional array of N=20 quantum dots.

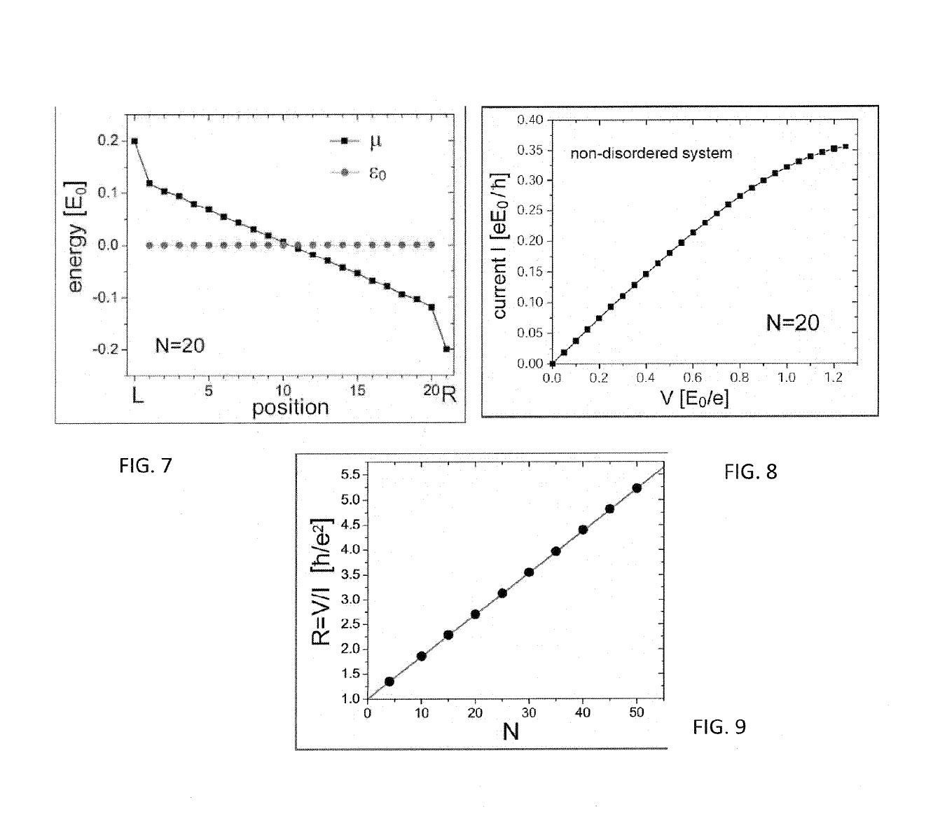

FIG. 7 shows how electro-chemical potential varies along an array of twenty dots in a non-disordered array, together with the energy level of each dot, ε₀. This is the energy level which is relevant for the transport of charge (i.e., the current) through the array of quantum dots. Here it is assumed that all quantum dots are identical such that the energy level is the same for all quantum dots. Moreover, it is assumed that all other energy levels in the dot are sufficiently far removed in energy from this energy level at ε₀. Sufficiently far removed here refers to a difference in energy that is larger than all other energy scales in the systems, which are not limited to k_{B} times temperature, e times applied bias, where k_{B} refers to the Boltzmann constant, and e is the electric charge. Here, L and R refer to the left and right contacts, respectively.

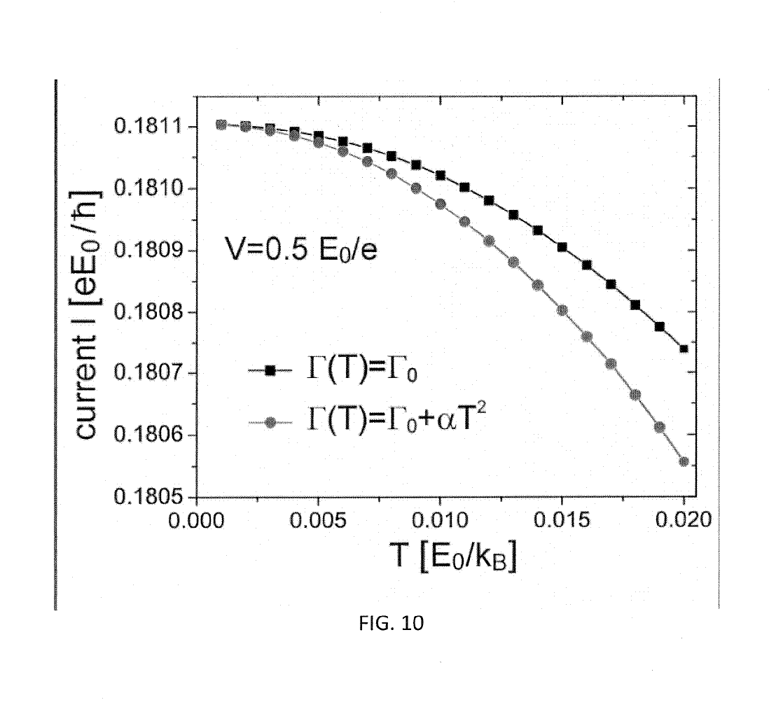

The variation of the ECP between the dots is a direct consequence of the resistive nature of this array of quantum dots. When the voltage (also referred to as bias) that is applied to the contacts is reversed, the flow of the current will change direction, but the magnitude of the current will remain unchanged for a non-disordered array of quantum dots. FIG. 8 shows a current/voltage relationship for the non-disordered array, and FIG. 9 shows a relationship between resistance and the number of quantum dots n. FIG. 10 shows a temperature dependence of the current in an array of quantum dots assuming that the inverse lifetime of the electrons (reflecting the dissipative nature of the quantum dots) Γ′(T)=Γ₀ is temperature independent, or varies with temperature as δ(T)=Γ₀+αT², where alpha is a constant number. This leads to a temperature dependence of the current given by I(T)=I₀−aTⁿ, where a is a constant number and where n is approximately 2. The temperature dependence of current arises from the curvature of the electronic bands.

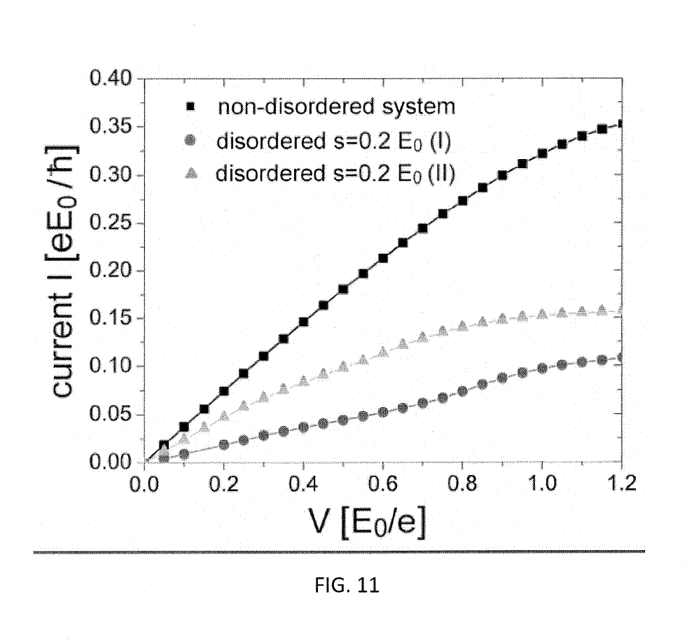

There are effects of confinement, disorder, dissipation, and interactions on the charge transport (i.e., the flow of electrons) in arrays of quantum dots. When the dots are not identical, and the energy levels of the dots are different from dot to dot, the array of quantum dots is considered to be disordered. For example, where the array of dots deviates from a perfect lattice, disorder arises from variations in the hopping tⱼₖ between the dots (in a non-disordered array of dots, all hopping t are identical). Where there are variations in dot size, disorder arises from variations in the energy position of the electronic levels ε₀(rᵢ). In FIG. 11, it is shown how the current depends on the applied voltage across a non-disordered and two disordered arrays of quantum dots. For the disordered arrays, it is assumed that disorder arises from variations between dots of the energy position of the energy levels. To describe this variation, a Gaussian probability distribution is used for Δε₀(rᵢ) with standard deviation s. As shown in FIG. 11, the disorder suppresses the current. However, the current depends on the specific realization of the disorder.

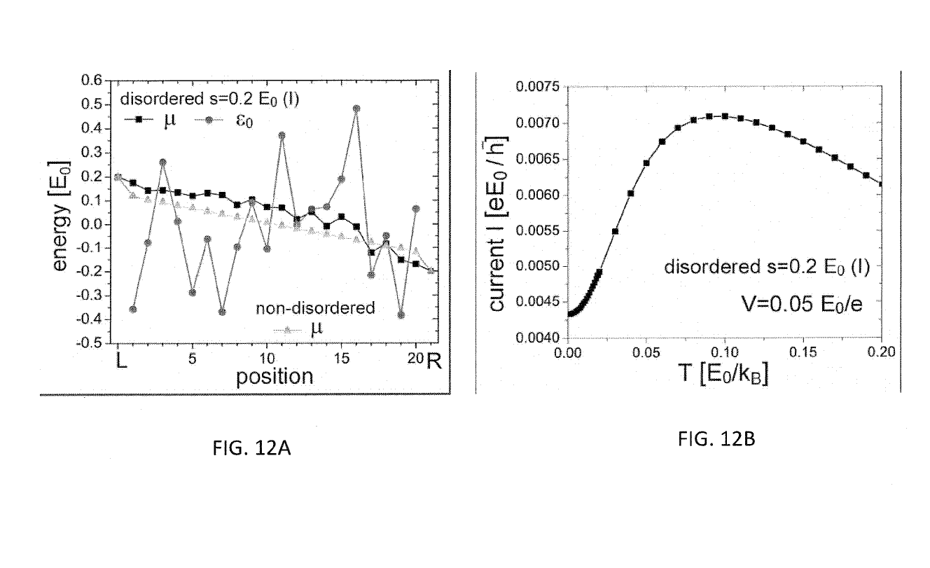

FIG. 12A shows the relationship between the position of a quantum dot in the array, the energy position of its energy level, and its chemical potential for a non-disordered and a disordered array of quantum dots. FIG. 12B shows the relationship between the total current through the array and temperature. The results in FIGS. 12A and 12B are shown for weakly disordered arrays, i.e., where t, Γ>s. As shown in FIG. 12A, μt(rᵢ) does not follow ε₀(rᵢ), and electrons tunnel through disordered dots. As shown in FIG. 12B, temperature generates excitations between the disordered energy level ε₀(rᵢ), and the current increases.

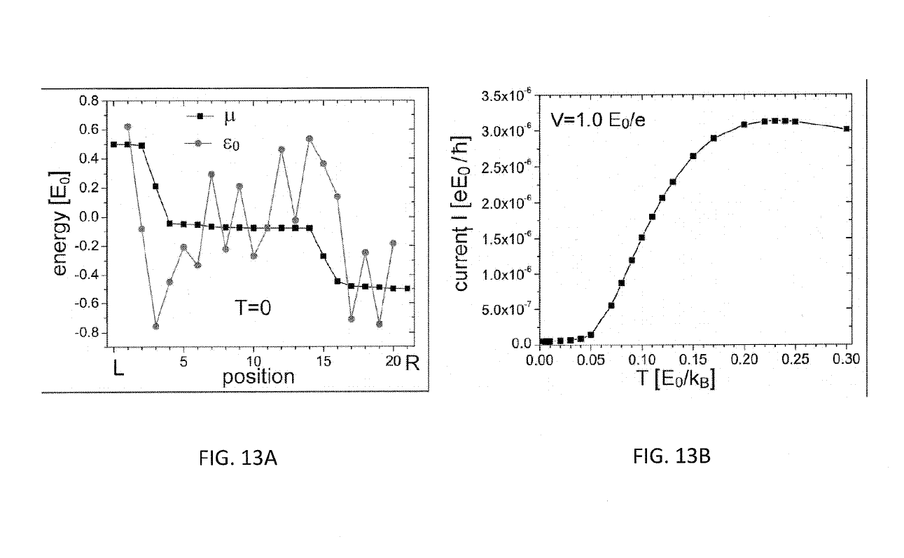

On the other hand, FIG. 13A shows the relationship between the position of a quantum dot in the array, the energy position of its energy level, and its chemical potential for a strongly disordered array where t, Γ<<s. FIG. 13B shows the relationship between the total current through the array and temperature for a strongly disordered array. In FIG. 13B, the temperature dependence of the total current is given by I(T)=I₀+αTⁿ, where n=1.8 . . . 2.2. This temperature dependence is different from the one found in variable range hopping, where ΔI(T)˜exp (−\sqrt{T₀/T}). This difference can be understood to arise from the curvature of the electronic bands, and the small system size that does not allow for self-averaging, which is significant in obtaining variable range hopping.

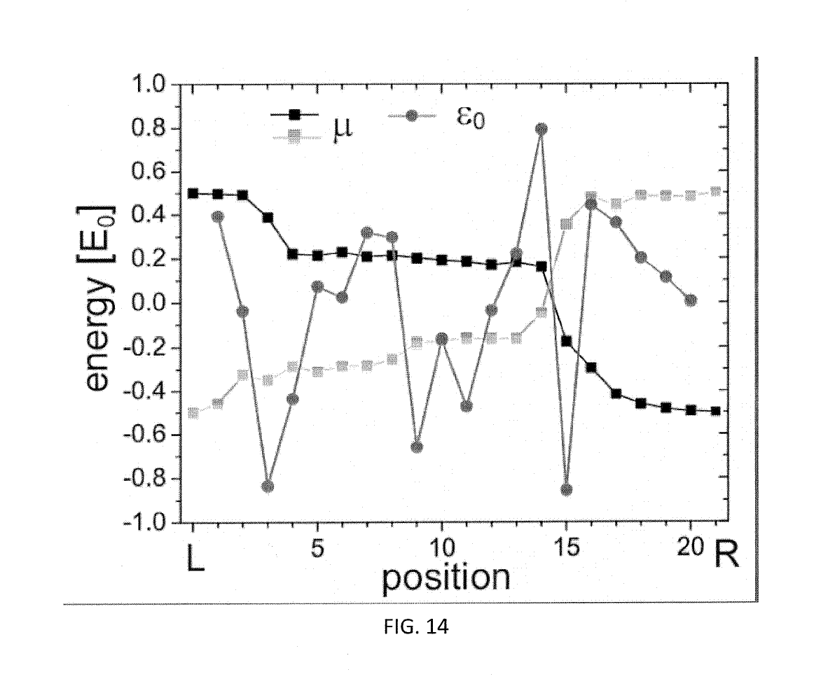

FIG. 14 shows a relationship between the position of a quantum dot in a one-dimensional disordered array of dissipative quantum dots, the energy position of the dots' energy level, and their chemical potential for a given potential difference (black line) and when the potential difference is reversed (light grey line). In a non-disordered array of quantum dots, the two lines describing the chemical potential are symmetric (i.e., they can be transformed into each other by reflection around the horizontal axis). However, as shown in FIG. 14 the disorder breaks the spatial symmetry of the energy position of the dots' energy levels, and therefore also the spatial symmetry of the chemical potentials under voltage reversal. As a result, the current flowing through the example array is different in magnitude under bias reversal by a factor of 3:

$$I = 8.89 \times {10}^{- 3} \frac{e}{ℏ} {E}_{0} , I = - 2.61 \times {10}^{- 2} \frac{e}{ℏ} {E}_{0} .$$

This provides a diode, in that when the bias across the diode (i.e., having disorder and dissipation (incoherence)) is reversed, the magnitude of the current through the diode changes as well.

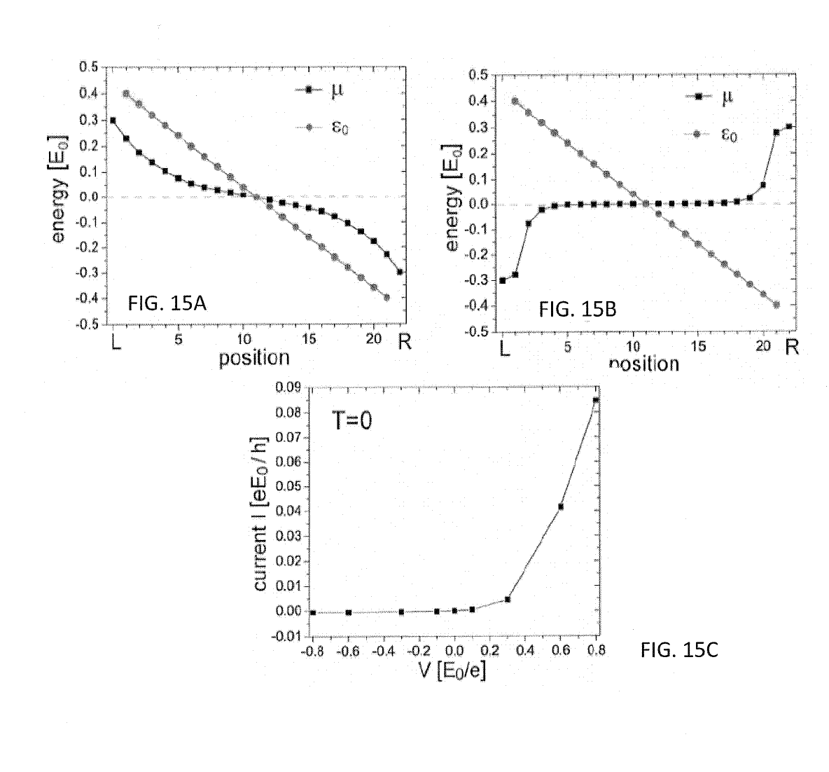

In order to make this diode more efficient (i.e., to increase the difference in the currents between a given bias and the reversed bias), one can, as a nonlimiting example, order the dots according to the energy position of the energy levels. FIGS. 15A and 15B show an example situation where quantum dots are arranged in such a way that the energy levels of the dots decrease from left to right. FIG. 15A shows the energy positions of the energy levels together with the electro-chemical potential (ECP) for a given bias, and FIG. 15B shows the energy positions of the energy levels together with the ECP for the reversed bias. As a result of this strong asymmetry in the ECP, the change in the magnitude of the current under bias reversal is significant:

$$I = 4.15 \times {10}^{- 2} \frac{e}{ℏ} {E}_{0} , I = - 5.08 \times {10}^{- 4} \frac{e}{ℏ} {E}_{0} .$$

In FIG. 15C, current is shown as a function of the applied bias (IV-characteristics).

Also, as shown in FIG. 15C, the arrangement of the quantum dots further provides a tailored forward bias in the diode. For forward bias, e.g., V>V₀, where V₀ can be tailored according to the arrangement of the quantum dots, and in a nonlimiting example, is a positive bias (V₀=0 corresponding to FIG. 15A), a current flows through the array of selectively disordered dissipative quantum dots. For the bias-reversed situation e.g., V<V₀, (V₀=0 corresponding to FIG. 15B), the magnitude of the current is greatly reduced. An efficient diode is thus provided.

Other electronic devices having tailored asymmetry in current flow can be provided. Such electronic devices need not require an applied bias, but instead can be provided as a valve to block electrons (or holes) from flowing into a particular direction.

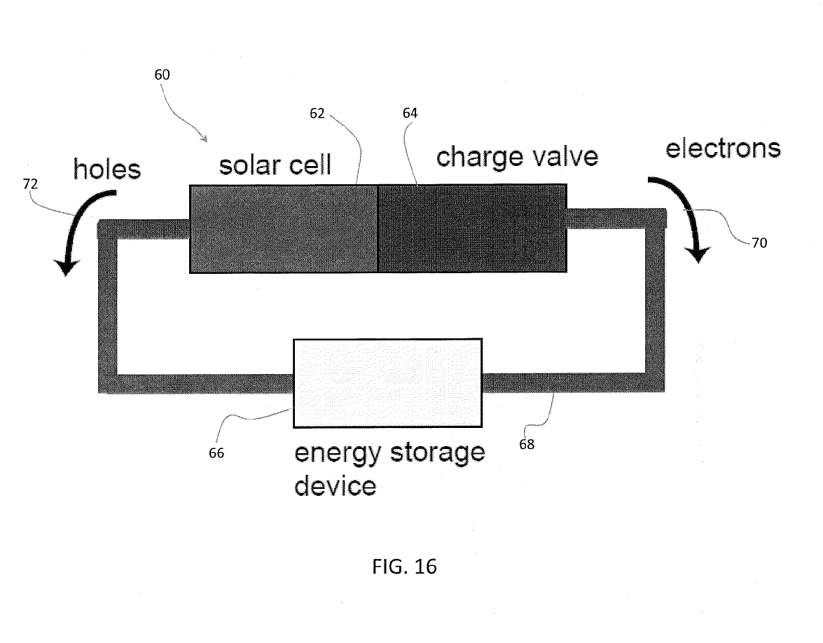

As another nonlimiting example, an electronic device such as a charge valve or electron valve, such as the valve shown in FIG. 16, can allow a one-way path for electrons within a device such as but not limited to solar cells. FIG. 16 shows an example embodiment solar device 60 including a solar cell 62, a charge valve 64, an energy storage device 66, such as but not limited to a battery, and leads 68. In the solar cell 62, light creates electron-hole pairs, which are then separated by the charge valve 64. The charge valve 64 prevents the flow of electrons 70 back to the solar cell 62, and therefore prevents the recombination of electrons and holes 72. The separated electrons 70 and holes 72 are then stored in the energy storage device 66. It will be appreciated that the electrons 70 and the holes 72 can be reversed in the device 60.

While various embodiments of the present invention have been shown and described, it should be understood that other modifications, substitutions, and alternatives are apparent to one of ordinary skill in the art. Such modifications, substitutions, and alternatives can be made without departing from the spirit and scope of the invention, which should be determined from the appended claims.

Various features of the invention are set forth in the appended claims.

1. An electronic device having a region formed from an array of dissipative quantum dots, the dissipative quantum dots being arranged according to their electronic structure to provide a tailored asymmetry in current flow through the region.

2. An electronic device according to claim 1, wherein the electronic device comprises a diode;
wherein the diode comprises:
a first contact;
a second contact;
the region being disposed between the first contact and the second contact and comprising the array of dissipative quantum dots;
wherein the dissipative quantum dots respectively vary in electronic structure between the first contact and the second contact;
wherein the dissipative quantum dots are arranged in the region according to their respective electronic structure to provide a tailored asymmetry in current flow between forward and reverse directions of applied potential differences across the region.

3. The electronic device of claim 1, wherein the respective electronic structure of the dissipative quantum dots results in different respective energy levels among the arranged dissipative quantum dots.

4. The electronic device of claim 3, wherein the different respective energy levels are different in one or more of energy level width and energy level position.

5. The electronic device of claim 1, wherein the array is one-dimensional.

6. The electronic device of claim 1, wherein the array is multi-dimensional.

7. The electronic device of claim 2, wherein the dissipative quantum dots are arranged in the region in one of respectively increasing energy position of energy levels between the first contact and the second contact and respectively decreasing energy position of energy levels between the first contact and the second contact.

8. The electronic device of claim 2, wherein the tailored asymmetry provides a tailored forward bias.

9. The electronic device of claim 2, wherein the tailored asymmetry provides a predetermined restriction to the current flow when the diode is reverse-biased.

10. The electronic device of claim 1, wherein the dissipative quantum dots are comprised of a material taken from the group consisting of cadmium-selenium (Cd—Se), silicon/silicon-germanium (Si/SiGe) heterostructures, and aluminum gallium arsenic/gallium arsenic (AlGaAs/GaAs) heterostructures.

11. The electronic device of claim 1, wherein the dissipative quantum dots are comprised of a metal material.

12. The electronic device of claim 1, wherein the dissipative quantum dots are comprised of a biological material.

13. The electronic device of claim 1, wherein the dissipative quantum dots are comprised of one of individual molecules and individual atoms.

14. The electronic device of claim 1, wherein the dissipative quantum dots respectively vary along the array in one or more of number of atoms, number of energy levels, and diameter.

15. The electronic device of claim 1, wherein the dissipative quantum dots in the region are disposed on a substrate.

16. The electronic device of claim 15, wherein the substrate is configured to selectively provide dissipation to each of the array of dissipative quantum dots.

17. The electronic device of claim 16,
wherein the substrate is selectively backgated at locations respective to the array of dissipative quantum dots;
whereby the backgated substrate selectively introduces a variation in the electronic structure in each of the quantum dots in the array of dissipative quantum dots.

18. The electronic device of claim 1, wherein the dissipative quantum dots in the region comprise free-floating networks.

19. The electronic device of claim 1, wherein the tailored asymmetry provides a difference in current magnitude between forward bias and reverse bias by a factor of five or larger.

20. The electronic device of claim 1, wherein the tailored asymmetry provides a difference in current magnitude between forward bias and reverse bias by a factor of 100 or larger.

21. The electronic device of claim 1, wherein the electronic device comprises a charge valve.

22. The electronic device of claim 21, further comprising:
a solar cell for creating electron-hole pairs;
an energy storage device coupled to the solar cell in a circuit;
wherein the charge valve is disposed in the circuit between the solar cell and the energy storage device;
wherein the charge valve prevents flow of electrons to the solar cell, thereby preventing a recombination of electrons and holes and providing separated electrons and holes;
whereby the separated electrons and holes can be stored in the energy storage device.

23. A method of making a diode comprising:
providing a region including a plurality of dissipative quantum dots arranged in an array, the dissipative quantum dots respectively varying in electronic structure to provide a tailored asymmetry in current flow between forward and reverse directions of applied potential differences across the provided region;
providing a first contact coupled to the region; and
providing a second contact coupled to the region.

24. The method of claim 23, wherein the providing a region comprises:
providing a plurality of dissipative quantum dots;
determining an electronic structure for the plurality of dissipative quantum dots.

25. The method of claim 24, wherein the determining an electronic structure comprises:
using a scanning tunneling microscope (STM) to measure a density of states in the quantum dots.

26. The method of claim 23, wherein the providing the region comprises atomically manipulating the plurality of dissipative quantum dots.

27. The method of claim 26, wherein the atomically manipulating uses a scanning tunneling microscope (STM) tip.

28. The method of claim 23, wherein the providing the region comprises arranging a plurality of quantum dots in the array such that respective distances between the arranged plurality of quantum dots permit electrons of the arranged quantum dots to tunnel into adjacent ones of the arranged quantum dots.

29. The method of claim 28, wherein the arranging comprises arranging the quantum dots on a substrate.

30. The method of claim 29, further comprising:
selecting the substrate based on an effect of the substrate on dissipation of the quantum dots.

31. The method of claim 28, wherein the arranging comprises arranging the quantum dots in a floating network.

32. The method of claim 28, further comprising:
causing the arranged plurality of quantum dots to be dissipative and thereby increasing a width of the respective energy levels of the arranged quantum dots.

33. The method of claim 28, wherein the causing comprises placing the quantum dots on a substrate such that electrons of the arranged plurality of quantum dots tunnel into an electronic level of the substrate.

34. The method of claim 33, wherein the substrate is configured to cause selective dissipation in the arranged plurality of quantum dots.

35. The method of claim 34, further comprising:
backgating the substrate to cause selective dissipation in the arranged plurality of quantum dots.

36. The method of claim 32, wherein the causing comprises interactions with phonons or other collective modes with the arranged plurality of quantum dots.

37. The method of claim 23, wherein respective ones of the array of dissipative quantum dots has a predetermined amount of decoherence such that an electron in each dissipative quantum dot can hop energy levels ten or more times before scattering.

38. The method of claim 23, wherein the providing a region comprises:
providing a plurality of quantum dots;
shifting respective energy levels of the provided plurality of quantum dots; and
arranging the plurality of quantum dots in ascending or descending order of energy of a particular energy level.

39. The method of claim 38, wherein said shifting comprises:
providing a backgated substrate;
wherein the arranging comprising coupling the arranged plurality of quantum dots to the backgated substrate.

40. The method of claim 38, wherein the causing comprises introducing phonons, spin collective modes or charge collective modes in the arranged quantum dots.

42. A method of controlling current flow comprising:
providing a diode comprising a first contact, a second contact, and a region disposed between the first contact and the second contact, the region comprising a plurality of dissipative quantum dots arranged in an array;
wherein the dissipative quantum dots respectively vary in electronic structure between the first contact and the second contact;
wherein the dissipative quantum dots are selectively arranged in said region according to their respective electronic structure to provide a tailored asymmetry in current flow between forward and reverse directions of applied potential differences across the region;
coupling a voltage source across the first contact and the second contact; and
applying a potential difference across the region.
